(19) United States
(12) Patent Application Publication
(10) Pub. No.: US 2025/0191946 A1
(43) Pub. Date: Jun. 12, 2025

(54) PROBE SYSTEM, METHOD FOR WAFER TEST MANAGEMENT SYSTEM IN A PROBE SYSTEM, AND NON-TRANSITORY COMPUTER-READABLE MEDIUM THEREOF

(71) Applicant: MPI CORPORATION, Zhubei City (TW)

(72) Inventors: Stojan KANEV, Zhubei City (TW); Chien Hung Chen, Zhubei City (TW); Ingo Berg, Zhubei City (TW); Frank Fehrmann, Zhubei City (TW); Phil Corson, Zhubei City (TW)

(21) Appl. No.: 18/973,516

(22) Filed: Dec. 9, 2024

Related U.S. Application Data
(60) Provisional application No. 63/607,575, filed on Dec. 8, 2023.

(51) Int. Cl. H01L 21/67; H01L 21/66

(52) U.S. Cl. CPC H01L 21/67288; H01L 22/30

(57) ABSTRACT

A probe system includes a wafer cassette, a wafer processing device, a computer and a transfer assembly. The wafer cassette stores a plurality of wafers. The wafer processing device is configured to test the wafer. The computer stores a test recipe, displays a plurality of virtual wafers corresponding to the plurality of first wafer cassette, creates a first virtual wafer group by selecting one or more virtual wafers from the first virtual wafer group, wherein the first virtual wafer group corresponds to the test recipe, and issues a load command. The transfer assembly transfers a selected wafer, which is one of the plurality of wafers stored in the first wafer cassette corresponding to a first virtual wafer within the first virtual wafer group, to the wafer processing device according to the load command for testing, wherein the wafer processing device tests the selected wafer based on the test recipe.

### CROSS-REFERENCE TO RELATED APPLICATIONS

This application claims priority to U.S. Provisional Applications No. 63/607,575 filed on Dec. 8, 2023, the entire contents of which are incorporated herein by reference.

### BACKGROUND OF THE INVENTION

The present invention relates to a probe system, method for wafer test management system in a probe system, and non-transitory computer-readable medium thereof. More specifically, the present invention relates to the probe system, method for wafer test management system in a probe system, and non-transitory computer-readable medium thereof which can edit a virtual wafer group and select the wafers to be tested based on the virtual wafer group.

For some semiconductor manufacturing facilities, their often equipped with a wafer processing system and a wafer cassette that is configured to contain a plurality of wafers. The wafer cassette may contain the wafers when they are stored and/or transferred among a wafer processing device that may be utilized during a semiconductor manufacturing process. The wafer cassettes include a plurality of slots, and each of these slots is configured to contain a respective wafer therein. Generally, the integrity of the wafers within the wafer cassette is maintained throughout the semiconductor manufacturing process to enable inventory control and/or to ensure that the wafers proceed through the various steps of the semiconductor manufacturing process in a desired order. In other words, a wafer to be processed might be removed from its designated wafer cassette during processing of the wafer on the wafer processing system. However, the wafer will be returned to the wafer cassette subsequent to completion of the processing. In addition, the wafer cassette will not be removed from the wafer processing system until each of the wafers that is present therein has been processed by the wafer processing system and returned to the wafer cassette.

In the traditional semiconductor manufacturing process, the processing steps that are performed by the various wafer processing systems are typically automated and may require minimal or no user intervention for completion thereof. In addition, the traditional semiconductor manufacturing process typically will utilize safeguards and/or interlocks to ensure that the wafer is returned to its designated wafer cassette, to prevent unintentional interruption of a processing step, and to restrict combining wafers from different wafer cassettes into another wafer cassette. However, due to maintain the integrity of the wafers in the wafer cassette, when the users of the traditional semiconductor manufacturing process complete testing a wafer under one test recipe that includes certain test conditions and need to test the wafer under another test recipe, they must manually replace the wafers in the wafer cassette or replace the entire wafer cassette. As a result, this requires additional manual intervention by the users, leading to significant amount of time being wasted. In view of this, it is important to overcome the problem in the art.

### SUMMARY OF THE INVENTION

To overcome at least the aforesaid problem, the present invention provides a probe system. The probe system may comprise a first physical wafer cassette, a wafer processing device, a computer and a transfer assembly, wherein the computer is programmed to control the operation of the probe system. The first wafer cassette is configured to store a plurality of physical wafers. The computer is configured to store a test recipe, display a plurality of virtual wafers corresponding to the plurality of first physical wafer cassette, create a first virtual wafer group by selecting one or more virtual wafers from the first virtual wafer cassette, wherein the first virtual wafer group corresponds to the test recipe, and issue a load command. The wafer processing device is controlled by the computer, which is configured to test the physical wafer. The transfer assembly is controlled by the computer, which is configured to transfer a selected physical wafer, which is one of the plurality of physical wafers stored in the first physical wafer cassette corresponding to a selected virtual wafer within the first virtual wafer group, to the wafer processing device according to the load command for testing, wherein the wafer processing device is controlled by the computer tests the selected physical wafer based on the test recipe.

To overcome at least the aforesaid problem, the present invention also provides a method for managing wafer testing in a probe system, performed by a computer (14). The method may comprise the following steps: displaying a first virtual wafer cassette that represents a first physical wafer cassette, the first virtual wafer cassette comprising a plurality of virtual wafers, each of which corresponds to a physical wafer stored in the first physical wafer cassette; creating a first virtual wafer group by selecting one or more virtual wafers from the first virtual wafer cassette, wherein the first virtual wafer group is associated with a test recipe for scheduling and managing a selected virtual wafer within the first virtual wafer group; issuing a load command to transfer a selected physical wafer from the first physical wafer cassette based on the first virtual wafer group, wherein the selected physical wafer is one of the plurality of physical wafers stored in the first physical wafer cassette corresponding to the selected virtual wafer within the first virtual wafer group; and processing the selected physical wafer based on the test recipe.

To overcome at least the aforesaid problem, the present invention also provides a probe system. The probe system may comprise a first physical wafer cassette, a wafer processing device, a computer and a transfer assembly. The first wafer cassette is configured to store a plurality of physical wafers. The computer is programmed to control the operation of the probe system according to the method for managing wafer testing in a probe system described above. The wafer processing device is controlled by the computer, which is configured to test the physical wafer. The transfer assembly is controlled by the computer, which is configured to transfer a selected physical wafer, which is one of the plurality of physical wafers stored in the first physical wafer cassette corresponding to a selected virtual wafer within the first virtual wafer group, to the wafer processing device according to the load command for testing, wherein the wafer processing device is controlled by the computer tests the selected physical wafer based on the test recipe.

The present invention further provides a non-transitory computer-readable medium. The non-transitory computer-readable medium may comprise computer-readable instructions that, when executed, direct a probe system to perform a method.

The present invention further provides a semiconductor device tested by the above-mentioned method.

The present invention further provides a method of testing an unpackaged semiconductor device by the above-mentioned method for managing wafer testing in a probe system.

The present invention further provides a method of producing a tested semiconductor device by the above-mentioned method for managing wafer testing in a probe system.

As disclosed above, in the present invention, each wafer is held in individual wafer tray within the wafer cassette, so the wafers may be loaded and unloaded individually. Therefore, in the semiconductor manufacturing process, if it is necessary to test the wafers under different test recipes, the probe system, the method for managing wafer testing in a probe system, the non-transitory computer-readable medium, the semiconductor device, the method of testing an unpackaged semiconductor device, and the method of producing a tested semiconductor device provided according to the present invention only need to establish the virtual wafer groups corresponding to each test recipe, and based on the virtual wafer groups, load or unload the corresponding wafers from the individual wafer trays. As a result, as compared to the traditional semiconductor manufacturing process, this flexibility significantly improves the efficiency of wafer management.

The summary of the invention is not intended to limit the present invention, but merely provides basic profile of the present invention. The details of the present invention will be described with various embodiments as presented below.

### BRIEF DESCRIPTION OF DRAWINGS

FIG. 1 illustrates a schematic view of a probe system according to some embodiments of the present invention.

FIG. 2 illustrates a schematic view of how a probe system creates a virtual wafer group according to some embodiments of the present invention.

FIG. 3 illustrates a schematic view of how a probe system creates multiple virtual wafer groups according to some embodiments of the present invention.

FIG. 4 illustrates a schematic view of how a probe system selects virtual wafers from multiple virtual wafer cassettes to create a virtual wafer group according to some embodiments of the present invention.

FIG. 5 illustrates a list used to display a testing status of the virtual wafer cassette according to some embodiments of the present invention.

FIG. 6 illustrates a list used to display an attribute information and its values of a virtual wafer according to some embodiments of the present invention.

FIG. 7 illustrates a flowchart for describing a method for managing wafer testing in a probe system according to some embodiments of the present invention.

### DETAILED DESCRIPTION OF THE INVENTION

The embodiments as disclosed below are not intended to limit the present invention to any specific environment, applications, structures, processes or situations. In the attached drawings, elements which are not directly related to the present invention are omitted from depiction. Dimensions and dimensional relationships within individual elements in the attached drawings are only exemplary examples and are not intended to limit the present invention. Unless stated particularly, same element numerals may correspond to same elements in the following description without inconsistency with the present invention.

The terminology used herein is for the purpose of describing the embodiments only and is not intended to limit the present invention. The singular forms “a” and “an” are intended to include the plural forms as well, unless the context clearly indicates otherwise. The terms “comprises,” “comprising,” “includes,” “including,” etc., specify the presence of the stated features, integers, operations, elements, and/or components, but do not preclude the presence or addition of one or more other features, integers, operations, elements, components, and/or groups thereof. The term “and/or” includes any and all combinations of one or more of the associated listed items. Although the terms “first”, “second” and “third” etc., may be used herein to describe various elements, these elements should not be limited by these terms. These terms are merely used to distinguish one element from other elements. Thus, for example, a first element described below could also be termed a second element, without departing from the spirit and scope of the present invention.

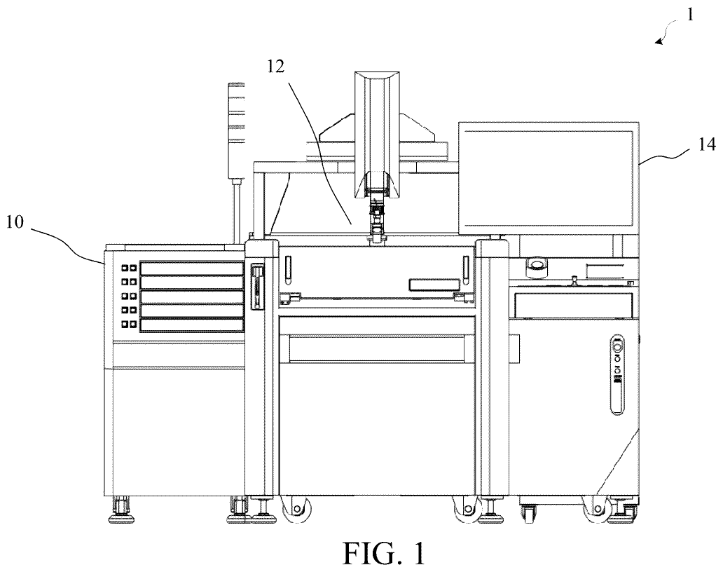

Some embodiments of the present invention relate to a probe system (which is referred to as a “probe system 1” hereinafter). FIG. 1 illustrates, a schematic view of the probe system 1 according to some embodiments of the present invention. The contents shown in FIG. 1 are provided only for illustrating embodiments of the present invention and should not be construed as any limitations on the present invention.

As shown in FIG. 1, the probe system 1 basically comprise, for example, a physical wafer cassette 10, a wafer processing device 12, a computer 14 and a transfer assembly (not shown), and the physical wafer cassette 10, the wafer processing device 12 and the transfer assembly are controlled by the computer 14.

The physical wafer cassette 10 may be configured to store a plurality of physical wafers (real wafers). For example, the physical wafer cassette 10 may comprise 5 independent wafer trays, allowing for the storage of a total of 5 physical wafers. In some embodiments, the physical wafer cassette 10 may comprise 25 independent wafer trays, allowing for the storage of a total of 25 physical wafers. It is noted that, the number of wafer trays and the number of physical wafer stored in the physical wafer cassette are not limited by the present invention. In addition, the physical wafer may include and/or be any suitable substrate, semiconductor wafer, silicon wafer, and/or Group III-V semiconductor wafer, which may also be referred to herein as a semiconductor device or a device under test (DUT), but is not limited thereto.

The wafer processing device 12 may comprises a probe assembly, a positioning assembly, a signal processing assembly, and a chuck.

The probe assembly may be configured to physically contact the physical wafers. Specifically, the probe assembly composed of one or more probes, along with one or more cables or other connection media used to electrically connect the probe assembly to the computer 14. In addition, the probe(s) may be any of various known probe tip, probe card, an RF probe, multi-wafer prober, semi-automatic prober, fully-automatic prober, needle probe, pyramid probe, membrane probe, space transformer, interposer or electrical conduit, etc., but is not limited thereto, and arranged to contact, process and test the physical wafer, adjust its internal temperature, and automatically align the physical wafer.

The positioning assembly may be configured to selectively vary a relative orientation between the chuck and the probe assembly. In addition, the signal processing assembly may be implemented as a signal generation and analysis assembly, which may be configured to generate a test signal, with the test signal being provided to the physical wafer and receive a resultant signal of the test from the physical wafer.

The chuck may be configured to receive the physical wafer from the physical wafer cassette 10 and/or support and locate the physical wafer within the wafer processing device 12. Specifically, the chuck may be any of various known electrostatic chuck, vacuum chuck or thermal chuck, etc., but is not limited thereto.

The computer 14 may be implemented as a main control unit, that includes a control host and a display interface. The main control unit may be a programmable specific integrated circuit that is capable of operating, storing, outputting/inputting or the like, and it may receive and process various coded instructions, thereby performing various logical operations and arithmetical operations and outputting corresponding operation results. Specifically, this main control unit can be used to store the test recipes required for testing physical wafers and execute the instructions necessary for testing the physical wafers. Furthermore, the display interface may be implemented as an LCD screen or a touch screen, but is not limited thereto, and may be configured to display a graphical user interface (GUI) for operation. On the other hand, the computer 14 may be configured to generate a load command or an unload command for load or unload the physical wafers.

The transfer assembly may be configured to transfer one or more wafers between the physical wafer cassette 10 and the wafer processing device 12. This may include initially transferring a physical wafer from the physical wafer cassette 10 to the wafer processing device 12 and subsequently transferring the physical wafer from the wafer processing device 12 back to the physical wafer cassette 10 for storage, such as after the completion of a test operation thereon. In addition, the transfer assembly may include or be a transfer robot, which may also be referred to as a transfer structure or a transfer device.

In the semiconductor manufacturing process, when the user receives one or more case(s) of the physical wafers, one physical wafer may be placed into the physical wafer cassette 10 and transferred to the wafers processing device 12 by the transfer assembly. Subsequently, the wafers processing device 12 may be configured to scan the physical wafers to obtain the physical wafer's attribute information (i.e., wafer diameter, wafer identifier and test temperature, wafer map information, etc.). In some cases, the wafers processing device 12 may scan a Bar Code of the physical wafers using Radio Frequency Identification (RFID) to obtain the physical wafer's attribute information. It is noted that, Each physical wafer in one or more case(s) of physical wafers basically has the same wafer diameter or other attribute information. Then, the user may place the one or more cases of physical wafers into the physical wafer cassette 10 for storage, that is, all physical wafers in the physical wafer cassette 10 have the same wafer diameter or other attribute information, and the computer 14 may set the wafer numbers. Moreover, the wafer identifier od the physical wafers can be the default, or they can be assigned after the physical wafers are stored in the physical wafer cassette 10.

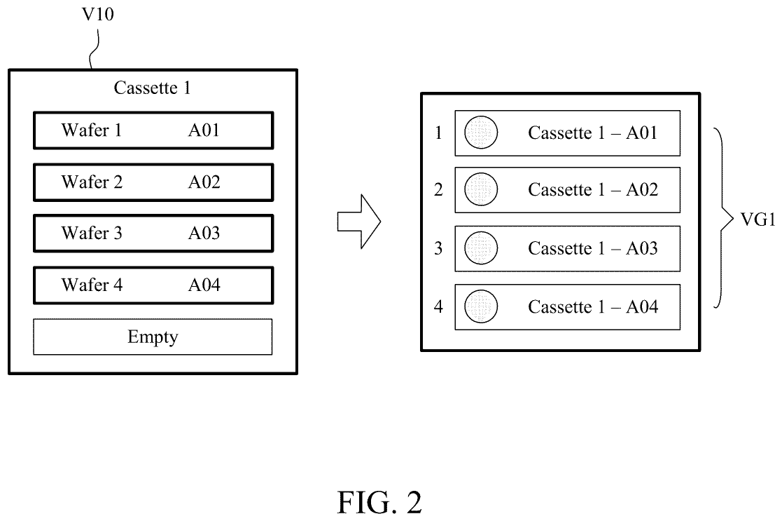

How the probe system 1 creates a virtual wafer group VG1 will be illustrated below with reference to FIG. 2. FIG. 2 illustrates a schematic view of how the probe system 1 creates the virtual wafer group VG1 according to some embodiments of the present invention. The contents shown in FIG. 2 is only for exemplifying the embodiment of the present invention, and are not intended to limit the scope claimed in the present invention.

As shown in FIG. 2, after the user obtains the attribute information of the physical wafer cassette 10, they can sequentially place the physical wafers into the wafer trays of the physical wafer cassette 10 according to testing requirements or test recipe. Subsequently, the display interface of the computer 14 may display a virtual wafer cassette V10 that represents the physical wafer cassette 10, the virtual wafer cassette V10 includes a plurality of virtual wafers, each of which corresponds to a physical wafer stored in the physical wafer cassette 10. In addition, the virtual wafer cassette V10 also includes a number of the virtual wafer trays, which are equal to the number of physical wafers, wherein the virtual wafer cassette V10 represents the physical wafer cassette 10, and the virtual wafer cassette V10 includes the wafer number (e.g., wafer 1, wafer 2, wafer 3, wafer 4, and wafer 5) and their wafer identifiers 10 (e.g., A01, A02, A03, A04 and A05).

For example, the four physical wafers corresponding to a default test recipe (e.g., testing the physical wafer of 300 mm diameter at 25° C.) can be placed into the physical wafer cassette 10. In this case, the display interface of the computer 14 may display the virtual wafer cassette V10 (named “Cassette 1”), which includes four virtual wafers (i.e., A01, A02, A03 and A04) loaded in four virtual wafer trays, while the fifth virtual tray is shown as empty. Furthermore, the physical wafer cassette 10 may have any number of unoccupied wafer trays, and additional physical wafers can be freely added to the physical wafer cassette 10, or physical wafers in any tray can be replaced. The wafer diameter or other attribute information of the added physical wafers must be the same as the physical wafers already in the physical wafer cassette 10, ensuring the physical wafer cassette 10 matches the virtual wafer cassette V10. For example, When transferring an additional physical wafer to the physical wafer cassette 10 by the transfer assembly, the wafer diameter of the additional physical wafer is the same as the plurality of physical wafers stored in the physical wafer cassette 10.

In some embodiments, the display interface of the computer 14 may display the wafer identifiers on the virtual wafers, the status of the physical wafers and other attribute information such as wafer diameter and test temperature can also be shown.

Referring to FIG. 2, one or more virtual wafers can be selected on the computer 14 based on the test recipe to create a virtual wafer group VG1, and the computer 14 may define a wafer sequence for these virtual wafers (e.g., 1, 2, 3, and 4). For example, if the test recipe requires testing of 4 physical wafers (i.e., A01, A02, A03 and A04), a virtual wafer group VG1 can be created by selecting the virtual wafers A01, A02, A03 and A04) from the virtual wafer cassette V10, wherein the virtual wafer group VG1 is associated with the test recipe for scheduling and managing a selected virtual wafer within the virtual wafer group VG1. Then, the computer 14 can set a status of these virtual wafers to “active”. Next, the computer 14 can issue a load command to the transfer assembly.

According to the load command, the transfer assembly may transfer a selected physical wafer from the physical wafer cassette 10, which is one of the plurality of wafers stored in the physical wafer cassette 10 corresponding to the selected virtual wafers within the virtual wafer group VG1, to the wafers processing device 12 based on the wafer sequence, allowing the wafers processing device 12 to test these physical wafers in sequence. Furthermore, after testing the physical wafer, the computer 14 can issue the next load command to the transfer assembly to unload the tested physical wafer and return it to the physical wafer cassette 10, and to load the next physical wafer. For example, first, the transfer assembly transfers a first physical wafer (named “first selected physical wafer”), which is one of the plurality of wafers stored in the physical wafer cassette 10 corresponding to a first virtual wafers within the virtual wafer group VG1 to the wafers processing device 12, then the wafers processing device 12 tests the first selected physical wafer based on the test recipe. After testing the first selected physical wafer, the computer 14 will issue the next load command to the transfer assembly to unload the first selected physical wafer and return it to the physical wafer cassette 10, and to load the next wafer until the test is done for all physical wafers in the physical wafer cassette 10.

In some embodiments, when the test is done for all wafers in the physical wafer cassette 10, any subsequent “load” command will cause the transfer assembly to return an error to the computer 14.

In addition, in some embodiments, after testing the wafer, the computer 14 can issue an unload command to the transfer assembly to unload the tested wafer. That is, the selected physical wafer from the wafer processing device 12 to the physical wafer cassette 10 when the test of the selected physical wafer is done.

In some embodiments, through the display interface of the computer 14, the virtual wafer group VG1 can be rearranged, and the specific virtual wafer can also be removed from the virtual wafer group VG1. Moreover, in some embodiments, the virtual wafers in the virtual wafer cassette V10 can be updated through the computer 14. For example, a refresh button can be set.

In some embodiments, the display interface of the computer 14 may be implemented as a touch screen providing a graphical user interface (GUI). That is, the virtual wafer group VG1 can be created through touch operations. For example, the virtual wafer group VG1 can be created by dragging one or more virtual wafer from the virtual wafer cassette V10. Additionally, the graphical user interface (GUI) can display the virtual wafer group VG1, and allow modification of the virtual wafer group VG1 by dragging on the graphical user interface (GUI). For example, the order of the virtual wafers in the virtual wafer cassette V10 can be rearranged by dragging, or the virtual wafers can be dragged from the inside of the virtual wafer cassette V10 to the outside to remove them.

In some embodiments, the display interface of the computer 14 may display the wafer identifier of the physical wafers, and the selected physical wafer can be transferred from the physical wafer cassette 10 to the wafers processing device 12 for testing by identifying the wafer identifier of the selected physical wafer.

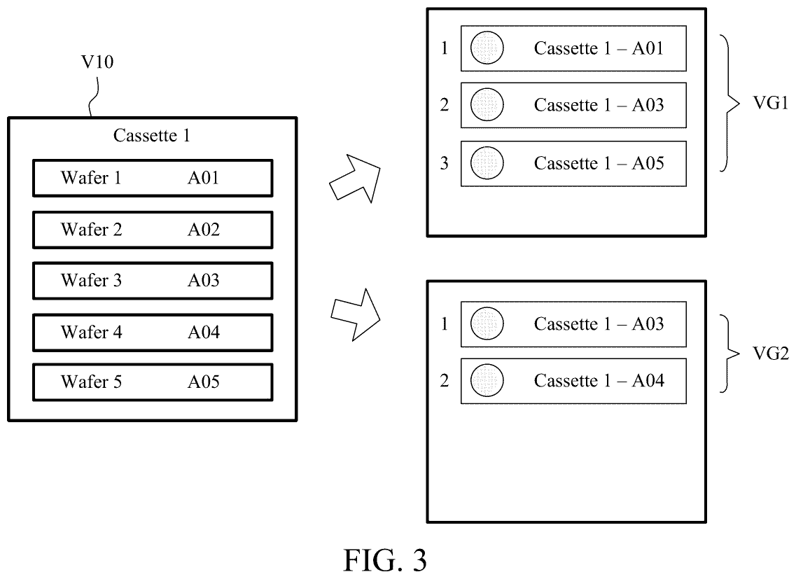

FIG. 3 provides a schematic view of how the probe system 1 creates multiple virtual wafer groups (i.e., the virtual wafer group VG1 and the virtual wafer group VG2) according to some embodiments of the present invention. The contents shown in FIG. 3 is provided only for illustrating embodiments of the present invention and should not be construed as any limitations on the present invention.

In some embodiments, after creating the virtual wafer group VG1 by selecting the virtual wafers from the physical wafer cassette 10, other virtual wafers, either previously selected or unselected, can further be selected from the virtual wafers from the physical wafer cassette 10, to create another virtual wafer group VG2, wherein the virtual wafer group VG2 is associated with another test recipe for scheduling and managing another selected virtual wafer within the virtual wafer group VG1. As shown in FIG. 3, for example, the virtual wafer cassette V10 includes five virtual wafers (i.e., A01, A02, A03, A04 and A05), on the computer 14, select the virtual wafers A01, A03 and A05 in that sequence to create the virtual wafer group VG1, then select the virtual wafers A03 and A04 in that sequence to create the virtual wafer group VG2. That is, the virtual wafer group VG1 and the virtual wafer group VG2 can be created with virtual wafers in any sequence, and the virtual wafers included in the virtual wafer group VG1 and the virtual wafer group VG2 can be the same (i.e., A03).

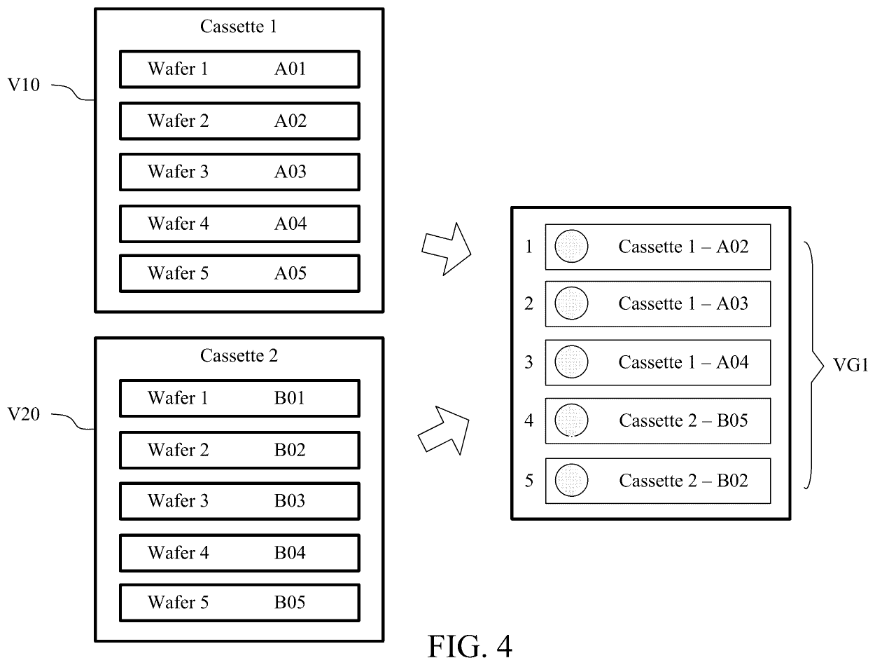

FIG. 4 provides a schematic view of how the probe system 1 selects virtual wafers from multiple virtual wafer cassettes (i.e., the first virtual wafer cassette V10 and the second virtual wafer cassette V20) to create the virtual wafer group VG1 according to some embodiments of the present invention. The contents shown in FIG. 4 is provided only for illustrating embodiments of the present invention and should not be construed as any limitations on the present invention.

In some embodiments, the display interface of the computer 14 may display another virtual wafer cassette that represents another physical wafer cassette. Thus, the user may select multiple virtual wafers from multiple virtual wafer cassettes to create the virtual wafer group VG1, wherein the physical wafers stored in the different physical wafer cassettes corresponding to these virtual wafer cassettes may have different wafer diameters or other attribute information. As shown in FIG. 4, for example, a first virtual wafer cassette V10 (named “Cassette 1”) includes five virtual wafers (i.e., A01, A02, A03, A04 and A05), and a second virtual wafer cassette V20 (named “Cassette 2”) also includes five virtual wafers (i.e., B01, B02, B03, B04 and B05), wherein the virtual wafers B01, B02, B03, B04 and B05 may correspond to the five physical wafers stored in the second physical wafer cassette. In this case, the user may select the virtual wafer A02, A03 and A04 from the first virtual wafer cassette V10 in that sequence, and select the virtual wafers B05 and B02 from the second virtual wafer cassette V20 in that sequence to create the virtual wafer group VG1. That is, the virtual wafer group VG1 can be created by selecting the plurality of virtual wafers from the first virtual wafer cassette V10 and the second virtual wafer cassette V20.

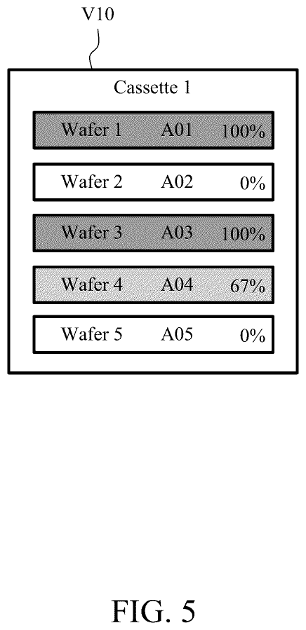

FIG. 5 illustrates a list used to display a testing status of the virtual wafer cassette according to some embodiments of the present invention. The contents shown in FIG. 5 is provided only for illustrating embodiments of the present invention and should not be construed as any limitations on the present invention.

In some embodiments, the display interface of the computer 14 may display a testing status of the first virtual wafer cassette V10, wherein the testing status comprises whether the testing of the plurality of physical wafers corresponding to the plurality of virtual wafers within the first virtual wafer cassette V10 are done. As shown in FIG. 5, the virtual wafer cassette V10 includes five virtual wafers (i.e., A01, A02, A03, A04 and A05), and the testing status of the first virtual wafer cassette V10 can show that A01 has completed testing (100%), A02 has not started testing (0%), A03 has completed testing (100%), A04 is currently being tested (67%), and A05 has not started testing (0%). In some embodiments, the testing status can be displayed using different colors. For example, the virtual wafers that have completed testing may be shown in dark gray or dark green, while the virtual wafers are currently being tested may be shown in light gray or yellow, but is not limited thereto.

In some embodiments, the computer 14 may store the testing status of the first virtual wafer cassette V10 and the test recipe along with the associated the virtual wafer group VG1. Then, when testing another physical wafer based on the test recipe or another test recipe with attributes similar to the test recipe., the user can recall the test recipe and the virtual wafer group VG1 by the computer 14.

In some embodiments, the computer 14 may also has a function to interrupt testing. For example, when the selected physical wafer stored in the physical wafer cassette 10 is currently being tested, the testing of the selected physical wafer can be interrupted, and the computer 14 may store the testing status of the first virtual wafer cassette V10 and the test recipe along with the associated first virtual wafer group VG1. Then, the user may replace the physical wafer cassette 10 with another physical wafer cassette, and resuming the testing of the physical wafers stored in the physical wafer cassette 10 that are not done based on the testing status, when the physical wafers stored in another physical wafer cassette are done. This way, there is no need to reconfigure the test recipe for the first virtual wafer cassette V10.

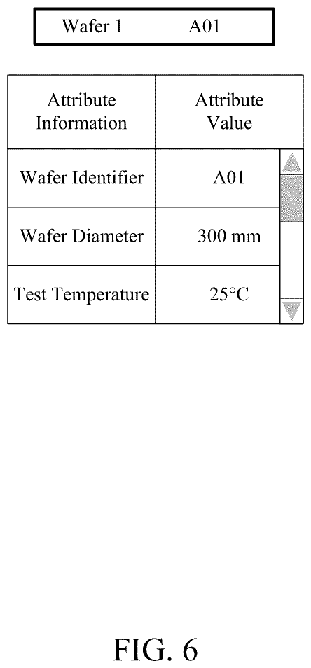

In some embodiments, each virtual wafer may also include a scroll box below its graphic to display a list of the customized attribute information and its values, as shown in FIG. 6. FIG. 6 provides a schematic view of a list used to display an attribute information and its values of the virtual wafers. The contents shown in FIG. 6 is provided only for illustrating embodiments of the present invention and should not be construed as any limitations on the present invention. In addition, an create button can be set or the list to update the attribute information and its values.

In some embodiments, the probe system 1 may include functions for adjusting the temperature of the wafer processing device 12 and for automatically aligning the physical wafer in the wafer processing device 12. Specifically, after transferring the physical wafer (e.g., the selected physical wafer), which is one of the plurality of physical wafers stored in the physical wafer cassette 10 corresponding to the virtual wafers within the virtual wafer group VG1, to the wafer processing device 12, and before the wafer processing device 12 tests the selected physical wafer, a wafer soaking time can be set according to a temperature in the wafer processing device 12 and a predetermined temperature. Then, the wafer processing device 12 can adjust the temperature in the wafer processing device 12 to the predetermined temperature. Subsequently, the automatic alignment is initiated when the temperature in the wafer processing device 12 reaches the predetermined temperature. Additionally, in some embodiments, the probe system 1 may also include other automation functions, such as the automated replacement of the probe assembly in the wafer processing device 12.

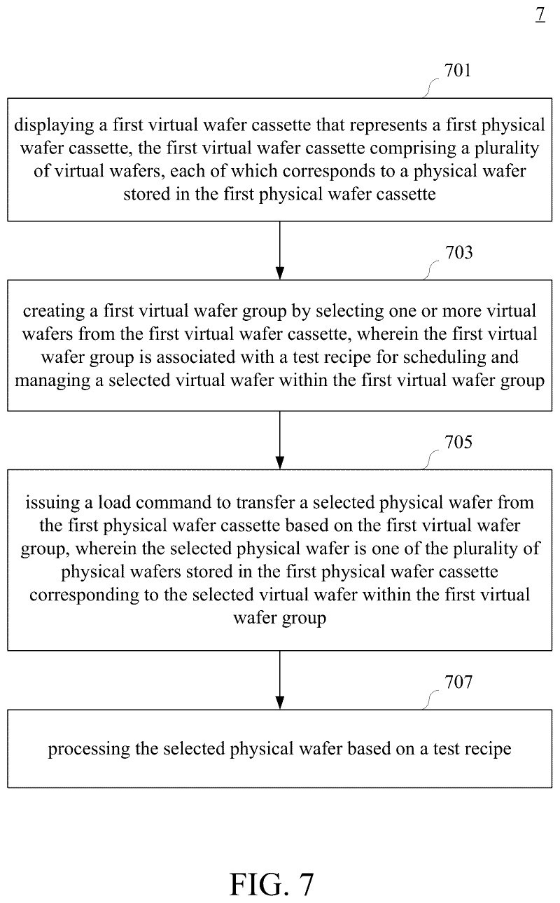

Some embodiments of the present invention relate to a method for managing wafer testing in a probe system, performed by a computer (which is referred to as a “method 2” hereinafter). FIG. 7 illustrates a flowchart for describing the method 2 according to some embodiments of the present invention, but the contents shown in FIG. 7 are only for exemplifying the embodiment of the present invention, and are not intended to limit the scope claimed in the present invention.

As shown in FIG. 7, the method 2 may comprise the following steps: displaying a first virtual wafer cassette that represents a first physical wafer cassette, the first virtual wafer cassette comprising a plurality of virtual wafers, each of which corresponds to a physical wafer stored in the first physical wafer cassette (marked as step “701”); creating a first virtual wafer group by selecting one or more virtual wafers from the first virtual wafer cassette, wherein the first virtual wafer group is associated with a test recipe for scheduling and managing a selected virtual wafer within the first virtual wafer group (marked as step “703”); issuing a load command to transfer a selected physical wafer from the first physical wafer cassette based on the first virtual wafer group, wherein the selected physical wafer is one of the plurality of physical wafers stored in the first physical wafer cassette corresponding to the selected virtual wafer within the first virtual wafer group (marked as step “705”); and processing the selected physical wafer based on a test recipe (marked as step “707”).

In some embodiments of the method 2, wherein before a probe system tests the selected physical wafer, further comprise: setting a wafer soaking time according to a temperature in the wafer processing device and a predetermined temperature; adjusting the temperature in the wafer processing device to the predetermined temperature; and initiating an automatic alignment when the temperature in the wafer processing device reaches the predetermined temperature.

In some embodiments, the method 2 may further comprise: issuing an unload command to transfer the selected physical wafer from a wafer processing device to the first physical wafer cassette when the test of the selected physical wafer is done.

In some embodiments, the method 2 may further comprise: creating a second virtual wafer group by selecting one or more virtual wafers from the first virtual wafer cassette, wherein the second virtual wafer group is associated with another test recipe for scheduling and managing another selected virtual wafer within the first virtual wafer group. In some embodiments, the method 2 may further comprise: displaying a second

virtual wafer cassette that represents a second wafer cassette, wherein the second virtual wafer cassette comprising a plurality of virtual wafers, each of which corresponds to another physical wafer stored in the second physical wafer cassette; and creating the first virtual wafer group by selecting the plurality of virtual wafers from the first virtual wafer cassette and the second virtual wafer cassette.

In some embodiments, the method 2 may further comprise: transferring an additional physical wafer to the first wafer cassette, wherein a wafer diameter of the additional physical wafer is the same as the plurality of wafers in the first physical wafer cassette.

In some embodiments, the method 2 may further comprise: providing a graphical user interface (GUI); and dragging the one or more virtual wafers from the first virtual wafer cassette on the graphical user interface (GUI) to create the first virtual wafer group.

In some embodiments, the method 2 may further comprise: displaying the first virtual wafer group; and modifying the first virtual wafer group by dragging on the graphical user interface (GUI).

In some embodiments of the method 2, wherein before the probe system tests the selected physical wafer, the method 2 may further comprise: transferring a first physical wafer stored in first physical wafer cassette to the wafer processing device for scanning to obtain an attribute information of the plurality of physical wafers stored in the first physical wafer cassette.

In some embodiments of the method 2, wherein the attribute information comprise the wafer diameter, wafer identifier, and test temperature required for testing.

In some embodiments, the method 2 may further comprise: storing the test recipe along with the associated the first virtual wafer group; and recalling the test recipe and the first virtual wafer group when testing another physical wafer based on the test recipe or another test recipe with attributes similar to the test recipe.

In some embodiments, the method 2 may further comprise: displaying a testing status of the first virtual wafer cassette wherein the testing status comprises whether the testing of the plurality of physical wafers corresponding to the plurality of virtual wafers within the first virtual wafer cassette are done.

In some embodiments, the method 2 may further comprise: interrupting the testing of the selected physical wafer; storing a testing status of the first virtual wafer cassette, wherein the testing status comprises whether the testing of the plurality of physical wafers corresponding to the plurality of virtual wafers within the first virtual wafer cassette are done; replacing the first physical wafer cassette with another physical wafer cassette; and resuming the testing of the physical wafers stored in the first physical wafer cassette that are not done based on the testing status, when the physical wafers stored in another physical wafer cassette are done.

In some embodiments, the method 2 may further comprise: assigning a wafer identifier to the plurality of physical wafers stored in the first physical wafer cassette and other physical wafer cassettes; and transferring another selected physical wafer from the first physical wafer cassette or other physical wafer cassettes by identifying the wafer identifier, for testing.

Some embodiments of the present invention relate to a probe system (not shown) that is configured to perform the above-mentioned method 2. In some embodiments, this probe system further comprise: a chuck, being configured to support the physical wafers; a probe assembly, being configured to physically contact the physical wafers; a positioning assembly, being configured to selectively vary a relative orientation between the chuck and the probe assembly; and a signal processing assembly, being configured to at least one of supply a test signal to the physical wafers and receive a resultant signal of the test.

In some embodiments of the method 2 may further comprise:

Each embodiment of the method 2 substantially corresponds to at least one embodiment of the probe system 1. Therefore, all the corresponding embodiments of the method 2 can be fully appreciated by those of ordinary skill in the art simply with reference to the above description of the probe system 1, even though not all the embodiments of the method 2 are described in detail above.

Some embodiments of the present invention relate to a computer-readable medium. The computer-readable medium may be a tangible object carrying a computer-readable program, for example, a non-transitory tangible machine-readable medium. The non-transitory tangible machine-readable medium may include: a non-transitory tangible machine-readable medium, a read-only memory (ROM), a flash memory, a floppy disk, a mobile hard disk, a magnetic tape, a network database, a cloud node or other tangible objects. In some embodiments, the computer-readable medium may also be a computer program product, and the computer program product refers to an object loaded with computer-readable programs and not limited to external forms, which is loaded by the electronic apparatus through various network transmissions.

Each embodiment of the computer-readable medium substantially corresponds to at least one embodiment of the probe system 1. Therefore, all the corresponding embodiments of the computer-readable medium can be fully appreciated by those of ordinary skill in the art simply with reference to the above description of the probe system 1, even though not all the embodiments of the computer-readable medium are described in detail above.

Some embodiments of the present invention relate to a semiconductor device tested by the method 2.

Some embodiments of the present invention relate to a method of testing an unpackaged semiconductor device by the method 2 for managing wafer testing in a probe system. In some embodiments, this method may further comprise: providing a computer programmed to perform the method 2; contacting the unpackaged semiconductor device by a probe assembly, wherein the probe assembly includes a plurality of probe tips configured to mechanically and electrically contact the unpackaged semiconductor device; communicating a test signal to or from the unpackaged semiconductor device; and processing the unpackaged semiconductor device.

Some embodiments of the present invention relate to a method of producing a tested semiconductor device by the method 2 for managing wafer testing in a probe system. In some embodiments, this method may further comprise: providing a computer programmed to perform the method 2; contacting the unpackaged semiconductor device by a probe assembly, wherein the probe assembly includes a plurality of probe tips configured to mechanically and electrically contact the unpackaged semiconductor device; communicating a test signal to or from the unpackaged semiconductor device; and processing the unpackaged semiconductor device.

The above embodiments are only examples for illustrating the present invention, and are not intended to limit the scope claimed in the present invention. Any other embodiments produced by modifying, changing, adjusting and integrating the above-mentioned embodiments shall all be included in the scope claimed in the present invention as long as they are not difficult for those of ordinary skill in the art to contemplate. The scope claimed in the present invention shall be governed by the claims.

What is claimed is:

1. A method (2) for managing wafer testing in a probe system (1), performed by a computer (14), comprising:
displaying a first virtual wafer cassette (V10) that represents a first physical wafer cassette (10), the first virtual wafer cassette (V10) comprising a plurality of virtual wafers, each of which corresponds to a physical wafer stored in the first physical wafer cassette (10);
creating a first virtual wafer group (VG1) by selecting one or more virtual wafers from the first virtual wafer cassette (V10), wherein the first virtual wafer group (VG1) is associated with a test recipe for scheduling and managing a selected virtual wafer within the first virtual wafer group (VG1);
issuing a load command to transfer a selected physical wafer from the first physical wafer cassette (10) based on the first virtual wafer group (VG1), wherein the selected physical wafer is one of the plurality of physical wafers stored in the first physical wafer cassette (10) corresponding to the selected virtual wafer within the first virtual wafer group (VG1); and
processing the selected physical wafer based on the test recipe.

2. The method (2) of claim 1, wherein before the probe system (1) tests the selected physical wafer, further comprising:
setting a wafer soaking time according to a temperature in a wafer processing device (12) and a predetermined temperature;
adjusting the temperature in the wafer processing device (12) to the predetermined temperature; and
initiating an automatic alignment when the temperature in the wafer processing device (12) reaches the predetermined temperature.

3. The method (2) of claim 1, further comprising:
issuing an unload command to transfer the selected physical wafer from a wafer processing device (12) to the first physical wafer cassette (10) when the test of the selected physical wafer is done.

4. The method (2) of claim 1, further comprising:
creating a second virtual wafer group (VG2) by selecting one or more virtual wafers from the first virtual wafer cassette (V10), wherein the second virtual wafer group (VG2) is associated with another test recipe for scheduling and managing another selected virtual wafer within the first virtual wafer group (VG1).

5. The method (2) of claim 1, further comprising:
displaying a second virtual wafer cassette (V20) that represents a second physical wafer cassette, wherein the second virtual wafer cassette (V20) comprising a plurality of virtual wafers, each of which corresponds to another physical wafer stored in the second physical wafer cassette; and
creating the first virtual wafer group (VG1) by selecting the plurality of virtual wafers from the first virtual wafer cassette (V10) and the second virtual wafer cassette (V20).

6. The method (2) of claim 1, further comprising:
transferring an additional physical wafer to the first physical wafer cassette (10), wherein a wafer diameter of the additional physical wafer is the same as the plurality of physical wafers stored in the first physical wafer cassette (10).

7. The method (2) of claim 1, further comprising:
providing a graphical user interface (GUI); and
dragging the one or more virtual wafers from the first virtual wafer cassette (V10) on the graphical user interface (GUI) to create the first virtual wafer group (VG1).

8. The method (2) of claim 7, further comprising:
displaying the first virtual wafer group (VG1); and
modifying the first virtual wafer group (VG1) by dragging on the graphical user interface (GUI).

9. The method (2) of claim 1, wherein before the probe system (1) tests the selected physical wafer, further comprising:
transferring a first physical wafer stored in the first physical wafer cassette (10) to the wafer processing device (12) for scanning to obtain an attribute information of the plurality of physical wafers stored in the first physical wafer cassette (10).

10. The method (2) of claim 9, wherein the attribute information comprise the wafer diameter, wafer identifier, and test temperature required for testing.

11. The method (2) of claim 1, further comprising:
displaying a testing status of the first virtual wafer cassette (V10), wherein the testing status comprises whether the testing of the plurality of physical wafers corresponding to the plurality of virtual wafers within the first virtual wafer cassette (V10) are done.

12. The method (2) of claim 11, further comprising:
storing the testing status of the first virtual wafer cassette (V10) and the test recipe along with the associated first virtual wafer group (VG1); and
recalling the test recipe and the first virtual wafer group (VG1) when testing another physical wafer based on the test recipe or another test recipe with attributes similar to the test recipe.

13. The method (2) of claim 11, further comprising:
interrupting the testing of the selected physical wafer;
storing the testing status of the first virtual wafer cassette (V10) and the test recipe along with the associated first virtual wafer group (VG1);
replacing the first physical wafer cassette (10) with another physical wafer cassette; and
resuming the testing of the physical wafers stored in the first physical wafer cassette (10) that are not done based on the testing status, when the physical wafers stored in another physical wafer cassette are done.

14. The method (2) of claim 1, further comprising:
assigning a wafer identifier to the plurality of physical wafers stored in the first physical wafer cassette (10); and
transferring the selected physical wafer from the first physical wafer cassette (10) by identifying the wafer identifier of the selected physical wafer, for testing.

15. A probe system (1) that is configured to test a physical wafer, comprising:
a first physical wafer cassette (10), being configured to store a plurality of physical wafers;
a computer (14) is programmed to control an operation of the probe system according to the method (2) of claim 1; and
a wafer processing device (12) is controlled by the computer (14), being configured to test the physical wafer;
a transfer assembly is controlled by the computer (14), being configured to transfer a selected physical wafer, which is one of a plurality of physical wafers stored in a first physical wafer cassette (10) corresponding to a selected virtual wafer within a first virtual wafer group (VG1), to the wafer processing device (12) according to a load command;
wherein the wafer processing device (12) test the selected physical wafer based on the test recipe.

16. The probe system (1) of claim 15, wherein the wafer processing device (12) further comprising:
a chuck, being configured to support the physical wafers;
a probe assembly, being configured to physically contact the physical wafers;
a positioning assembly, being configured to selectively vary a relative orientation between the chuck and the probe assembly; and
a signal processing assembly, being configured to at least one of supply a test signal to the physical wafers and receive a resultant signal of the test.

17. A probe system (1) that is configured to test a physical wafer, comprising:
a first physical wafer cassette (10), being configured to store a plurality of physical wafers;
a computer (14) is programmed to control an operation of the probe system, being configured to:
store a test recipe;
display a first virtual wafer cassette (V10) corresponding to the first physical wafer cassette (10);
create a first virtual wafer group (VG1) by selecting one or more virtual wafers from the first virtual wafer cassette (V10), wherein the first virtual wafer group (VG1) corresponds to the test recipe; and
issue a load command; and
a wafer processing device (12) is controlled by the computer (14), being configured to test the physical wafer;
a transfer assembly is controlled by the computer (14), being configured to transfer a selected physical wafer, which is one of the plurality of physical wafers stored in the first physical wafer cassette (10) corresponding to a selected virtual wafer within the first virtual wafer group (VG1), to the wafer processing device (12) according to the load command;
wherein the wafer processing device (12) is controlled by the computer (14) test the selected physical wafer based on the test recipe.

18. The probe system (1) of claim 17, wherein the wafer processing device (12) further comprising:
a chuck, being configured to support the physical wafers;
a probe assembly, being configured to physically contact the physical wafers;
a positioning assembly, being configured to selectively vary a relative orientation between the chuck and the probe assembly; and
a signal processing assembly, being configured to at least one of supply a test signal to the physical wafers and receive a resultant signal of the test.

19. A non-transitory computer-readable medium including computer-readable instructions that, when executed, direct a probe system (1) to perform the method (2) of claim 1.

20. A semiconductor device tested by the method (2) of claim 1.

21. A method of testing an unpackaged semiconductor device, comprising:
providing a computer programmed to perform the method (2) of claim 1;
contacting the unpackaged semiconductor device by a probe assembly, wherein the probe assembly includes a plurality of probe tips configured to mechanically and electrically contact the unpackaged semiconductor device;
communicating a test signal to or from the unpackaged semiconductor device; and
processing the unpackaged semiconductor device.

22. A method of producing a tested semiconductor device, comprising:
providing a computer programmed to perform the method (2) of claim 1;
contacting the unpackaged semiconductor device by a probe assembly, wherein the probe assembly includes a plurality of probe tips configured to mechanically and electrically contact the unpackaged semiconductor device;
communicating a test signal to or from the unpackaged semiconductor device; and
processing the unpackaged semiconductor device.
